(19) United States
(12) Patent Application Publication
(10) Pub. No.: US 2024/0057265 A1
(43) Pub. Date: Feb. 15, 2024

(54) STRESS-RELEASING SOLDER MASK PATTERN FOR SEMICONDUCTOR DEVICES AND RELATED SYSTEMS AND METHODS

(71) Applicant: Micron Technology, Inc., Boise, ID (US)

(72) Inventors: Kelvin Tan Aik Boo, Singapore (SG); Ling Pan, Singapore (SG)

(21) Appl. No.: 17/885,338

(22) Filed: Aug. 10, 2022

(51) Int. Cl. H05K 3/34; H05K 1/02

(52) U.S. Cl. CPC H05K 3/3452; H05K 1/0271; H05K 3/3436; H05K 2201/099

(57) ABSTRACT

Substrates having stress-releasing features, and associated systems and methods are disclosed herein. In some embodiments, the substrate includes a core layer, a metallization layer formed on an outer surface of the core layer, and a solder mask formed over the metallization layer and the outer surface. The metallization layer can include at least one bond pad and the solder mask can include a first opening exposing the bond pad. The first opening can be surrounded by a bonding region of the solder mask that thermally interfaces with the bond pad and/or any conductive structure bonded thereon. The solder mask can also include one or more second openings adjacent the first opening. Each of the second openings provides space for the solder mask to expand into to release stress due to thermal expansions of the bond pad, the solder mask, and/or the conductive structure during manufacturing and/or operation.

### TECHNICAL FIELD

The present technology is generally related to systems and methods for reducing cracks in a solder mask. In particular, the present technology relates to opening patterns in solder masks that release stress and related systems and methods.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, interconnecting circuitry, etc. To meet continual demands on decreasing size, individual semiconductor dies and/or active components are typically manufactured in bulk and then stacked on a printed circuit board (PCB) or other substrates. In turn, the PCB can be bonded to another component, such as the motherboard of a larger package. To facilitate electrical connection to the semiconductor dies and/or other components, PCBs typically include a metallization layer with designated bond pads and a solder mask material that insulates the metallization layer and includes openings that expose the designated bond pads.

### BRIEF DESCRIPTION OF THE DRAWINGS

FIG. 1A is an isometric view of a substrate for a semiconductor assembly configured in accordance with some embodiments of the present technology.

FIG. 1B is a partial cross-sectional view of the substrate of FIG. 1A configured in accordance with some embodiments of the present technology.

FIG. 1C is a close-up cross-sectional view of the substrate of FIG. 1A configured in accordance with some embodiments of the present technology.

FIG. 2 is a partially schematic top view of the substrate of FIG. 1C configured in accordance with some embodiments of the present technology.

FIG. 3A is a partially schematic cross-sectional view of a semiconductor device configured in accordance with some embodiments of the present technology.

FIG. 3B is a partially schematic, zoomed-out cross-sectional view of the semiconductor device of FIG. 3A in accordance with some embodiments of the present technology.

FIG. 4 is a partially schematic cross-sectional view of a semiconductor device configured in accordance with further embodiments of the present technology.

FIGS. 5A and 5B are partially schematic cross-sectional and bottom plan views, respectively, of a semiconductor device configured in accordance with further embodiments of the present technology.

FIG. 6 is a partially schematic top view of a substrate for use with a semiconductor device configured in accordance with some embodiments of the present technology.

FIG. 7 is a partially schematic isometric view of a substrate configured in accordance with further embodiments of the present technology.

FIG. 8 is a flow diagram of a process for manufacturing a substrate in accordance with some embodiments of the present technology.

FIG. 9 is a schematic view of a system that includes a semiconductor die assembly configured in accordance with embodiments of the present technology.

The drawings have not necessarily been drawn to scale. Further, it will be understood that several of the drawings have been drawn partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

As demands have continued to push for smaller and/or more densely packed semiconductor devices, many components of semiconductor devices and/or packages have continued to shrink and become more densely packed. For example, the bond pads on a printed circuit board (PCB), and the corresponding openings in the solder mask, can be decreased to allow more electrical bonds to be formed in a given area. However, as the bond pads and openings are decreased in size, the thermal interaction between the solder masks, the bond pads, and any conductive structure (e.g., solder balls) formed on the bond pads increases. In turn, the increase in the thermal interaction can cause cracks in the solder mask to form and/or propagate, sometimes causing failure in one or more of the bond pads. In some cases, the cracks can even cause a failure across an entire PCB through a complete crack therein and/or failure of one or more critical bond pads.

Substrates with features for mitigating crack formation and/or propagation, and associated systems and methods, are disclosed herein. In some embodiments, the substrate includes a core layer, a metallization layer formed on an outer surface of the core layer, and a solder mask formed over the metallization layer and the outer surface. The metallization layer can include at least one bond pad and a trace electrically coupled to the at least one bond pad. The trace can couple the bond pad to a via and/or other redistribution structure. The solder mask can include a first opening exposing the at least one bond pad. The first opening can be surrounded by a bonding region of the solder mask that thermally interfaces with the at least one bond pad and/or any conductive structure bonded thereon (e.g., a solder ball). The solder mask can also include one or more second openings adjacent the first opening. Each of the one or more second openings provides space for the bonding region of the solder mask to expand into during a thermal expansion of the at least one bond pad, the solder mask, and/or the conductive structure formed on the at least one bond pad. Accordingly, the second openings can help release stress in the solder mask that results from thermal expansions (especially non-uniform thermal expansion). As a result, the second openings can reduce crack formation and/or crack propagation.

In some embodiments, the solder mask includes a plurality of first openings, each of which can exposes an individual bond pad on the metallization layer. In such embodiments, the solder mask can also include a plurality of second openings adjacent each of the plurality of first openings. Similar to the discussion above, each of the plurality of second openings can provide a longitudinal space for portions of the solder mask proximate the plurality of first openings to expand into. Accordingly, the plurality of second openings can alleviate stress in the solder mask for each of the plurality of first openings. Additional details on the substrate, and related systems and methods, are set out below.

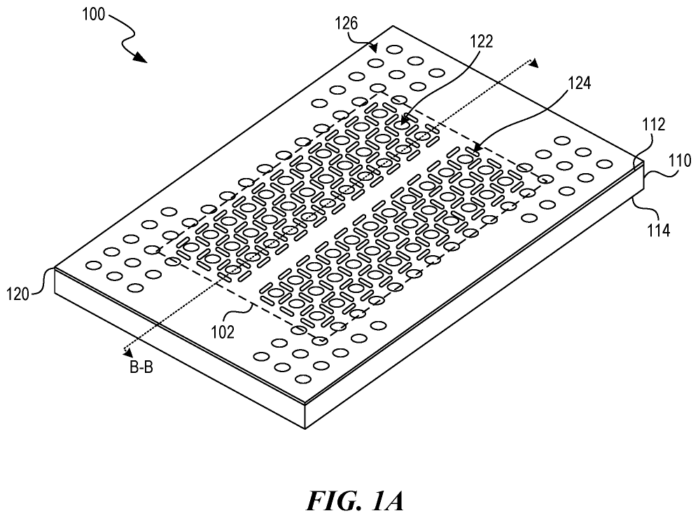

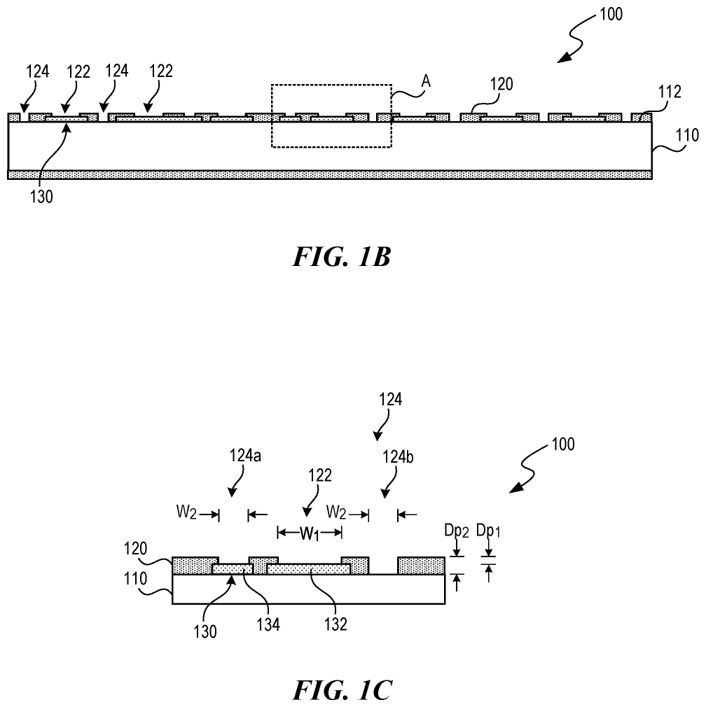

FIG. 1A is an isometric view of a substrate 100 for a semiconductor assembly in accordance with some embodiments of the present technology. In the illustrated embodiment, the substrate 100 includes a core layer 110 that has a first surface 112 (e.g., an upper surface and/or an outer surface) and a second surface 114 (e.g., a lower surface and/or an outer surface) opposite the first surface 112. The substrate 100 also includes solder mask 120 carried by the first surface 112. The solder mask 120 includes one or more first openings 122 (one labeled) positioned in a central region 102 of the substrate 100. The solder mask 120 also includes one or more second openings 124 (one labeled) that are each positioned adjacent to one or more of the first opening(s) 122. As described in more detail below, the first opening(s) 122 expose conductive structures (e.g., bonding portions of metallization layers, electrical and/or thermal bond pads, and the like) carried by the first surface 112 while the second opening(s) 124 help release stress in the solder mask 120 around the first opening(s) 122. As a result, the second opening(s) 124 can help reduce (or eliminate) cracks in the solder mask, conductive structures (e.g., solder structures, interconnects, conductive pillars, and the like), and/or the core layer 110 around the first opening(s) 122.

In the illustrated embodiment, the solder mask 120 also includes one or more additional openings 126 (one labeled) that are positioned in peripheral regions of the substrate 100. Similar to the first opening(s) 122, the additional opening(s) 126 can expose conductive structures carried by the first surface 112. However, the additional opening(s) 126 can be less prone to cracking issues (e.g., stress released through the longitudinal sides of the substrate 100) and/or less important to the overall functioning of the substrate 100. Accordingly, in some embodiments, the solder mask 120 does not include second opening(s) 124 positioned adjacent the additional opening(s) 126. For example, the second opening(s) can be included only adjacent to the first opening(s) 122 that are critical-to-function. The omission of the second opening(s) 124 from the peripheral region can help reduce manufacturing costs and time.

FIG. 1B is a partial cross-sectional view the substrate 100 in accordance with some embodiments of the present technology. In particular, FIG. 1B is a partial cross-sectional view taken along line B-B in FIG. 1A. As illustrated in FIG. 1B, the substrate 100 can include a metallization layer 130 formed on and/or carried by the first surface 112 of the core layer 110. Further, in the embodiment illustrated in FIG. 1B, the solder mask 120 can include an alternating arrangement of the first openings 122 (two labeled) and the second openings 124 (two labeled). In various other embodiments, the first and second openings 122, 124 can be arranged in any other suitable configuration. For example, each of the first opening(s) 122 can be individually surrounded by two or more second opening(s) (e.g., such that the cross-section view would show two second openings 124 for each of the first opening(s) 122). In another example, the first openings 122 can outnumber the second openings 124 (e.g., such that the cross-section view would show two first openings 122 for each of the second openings 124).

FIG. 1C is a close-up cross-sectional view of the substrate 100 in accordance with some embodiments of the present technology. In particular, FIG. 1C is a close-up view of the Region A of FIG. 1B illustrating additional details of the substrate 100. For example, the illustrated region includes a metal second opening 124a and a substrate second opening 124b each positioned adjacent to the first opening 122. The first opening 122 exposes a bonding portion 132 of the metallization layer 130, thereby providing a space for a solder structure (or other suitable interconnect) to electrically and/or thermally couple the metallization layer to another substrate, device, and/or structure. For example, in some embodiments, the core layer 110 is a package substrate with a redistribution layer at the first surface 112. In such embodiments, the bonding portion 132 exposed by the first opening 122 can allow the package substrate to be electrically coupled to one or more semiconductor dies attached to the package substrate. In another example, the bonding portion 132 exposed by the first opening 122 can allow the package substrate to be electrically coupled to a printed circuit board and/or another suitable carrier.

As discussed in more detail below, the metal and substrate second openings 124a, 124b are positioned to release stress in the solder mask 120 in the vicinity of the first opening 122. In particular, the metal and substrate second openings 124a, 124b are positioned to allow the solder mask 120 to expand into the open spaces with variations in temperature. For example, the second opening(s) 124 can be positioned between about 20 micrometers (μm) and about 100 μm apart from the first opening(s) 122 to provide a dedicated space for expansion. By providing a dedicated space for expansion, the metal and substrate second openings 124a, 124b can help alleviate problems caused by a mismatch between the coefficient of thermal expansion (CTE) between the bonding portion 132, the solder mask 120, and/or a relevant conductive structure (e.g., solder ball). As further illustrated in FIG. 1C, the metal and substrate second openings 124a, 124b in the solder mask 120 can also expose underlying structures. For example, in the illustrated embodiment, the metal second opening 124a exposes a non-bonding portion 334 of the metallization layer 130 (e.g., a trace, a portion of the trace, a peripheral portion of the bonding portion 132, and the like) while the substrate second opening 124b exposed the first surface 112 of the core layer 110.

In various other embodiments, the second openings 124 can each be positioned to intentionally expose certain structures in addition to releasing stress in the solder mask 120. For example, the second openings 124 can each be positioned to expose a non-bonding portion 134 of the metallization layer (e.g., to provide a backstop for the solder mask stripping process). In another example, the second openings 124 can each be positioned to expose the first surface 112 of the core layer 110 (e.g., to minimize the exposure of the metallization layer 130 through the solder mask 120).

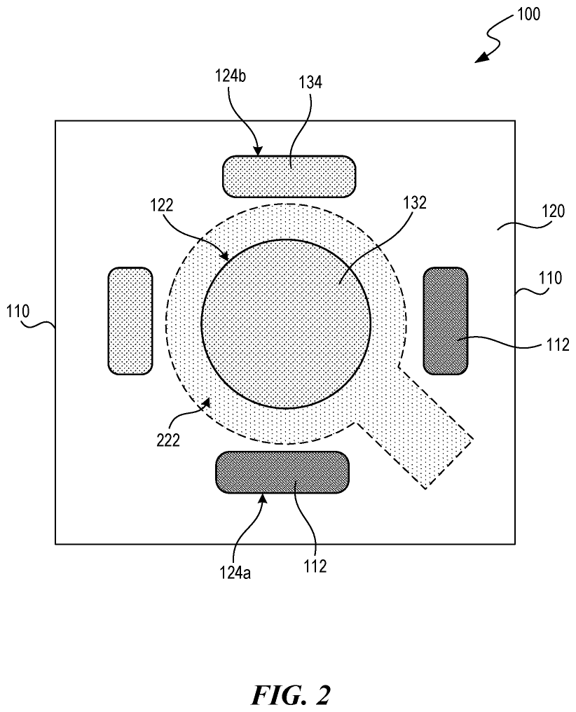

As further illustrated in FIG. 1C, the first and second openings 122, 124 can have varying depths and/or longitudinal footprints. For example, the first opening 122 has a first width W₁, while each of the second openings 124 has a second width W₂ that is smaller than the first width W₁. In various embodiments, the first opening 122 can have a width between about 0.25 millimeters (mm) and about 0.3 mm, or of about 0.3 mm; while each of the second openings 124 can have a width between about 0.005 mm and about 0.075 mm, or of about 0.015 mm. As a result, the first opening 122 can have a larger widthwise footprint than either of the second openings 124. In turn, the first opening 122 can have a length that is generally similar to (or greater than) the second openings 124 (see, e.g., FIG. 2). As a result, the first opening 122 can have a larger longitudinal footprint (sometimes also referred to herein as the cross-sectional area) than either of the second openings 124. For example, the cross-sectional area of the second openings 124 can be between about 0.02 percent the size of the first openings 122 to about 10 percent the size of the first openings 122, or between about 1 percent and about 5 percent the size of the first openings 122. The smaller cross-sectional area of the second openings 124 can be useful to provide the stress-releasing benefits of the second openings 124 while maintain relatively low exposure of the structures underlying the solder mask 120.

In another example illustrated in FIG. 1C, the first opening 122 has a first depth Dp₁ while the substrate second opening 124b has a second depth Dp₂ that is larger than the first depth Dp₁. The first depth Dp₁ corresponds to the thickness of the solder mask 120 over the bonding portion 132 while the second depth Dp₂ corresponds to the thickness of the solder mask 120 over the first surface 112 of the core layer 110. That is, the varying thicknesses can result from the varying depths of the underlying structures, using the underlying structures as a stopping point for an etching process. For example, the same etching process can form the first opening 122 to the first depth Dp₁ and the substrate second opening 124b to the second depth Dp₂ while being stopped by the bonding portion 132 and the core layer 110 in the corresponding openings. In various embodiments, the first depth Dp₁ is between about 10 μm and about 20 μm while the second depth Dp₂ is between about 0.05 mm and about 0.25 mm.

As further illustrated in FIG. 1C, the metal second opening 124a has the first depth Dp₁, for example resulting from a generally planar metallization layer 130. However, in some embodiments, the metal second opening 124a (and/or any openings exposing a non-bonding portion 134 of the metallization layer 130) has a third depth that is different than the first and second depths Dp₁, Dp₂. For example, the third depth can be intermittent the first and second depths Dp₁, Dp₂, corresponding to a non-bonding portion 134 that is not as thick as the bonding portion 132 (e.g., when the bonding portion 132 includes an elevated bond pad). Similarly, the second openings 124 can each have a different widthwise (or lengthwise) footprint, allowing for the formation of complex patterns to alleviate stress in the solder mask 120.

FIG. 2 is a partially schematic top view of the substrate 100 of FIG. 1C in accordance with some embodiments of the present technology. In the illustrated embodiment, the solder mask 120 includes four second openings 124 positioned at the cardinal sides of the first opening 122. In various other embodiments, the solder mask 120 can include any suitable number of the second openings 124 (e.g., one, two, three, five, ten, etc.). In the illustrated embodiment, the first opening 122 exposes the bonding portion 132 of the metallization layer 130. In turn, the four second openings 124 include two metal second openings 124a exposing two non-bonding portions 134 of the metallization layer 130, and two substrate second openings 124b exposing the first surface 112 of the core layer 110. In various other embodiments, the second openings 124 can include any suitable number (including none) exposing the non-bonding portion 134 and/or any suitable number (including none) exposing the first surface 112. Further, in some embodiments, one or more of the second openings 124 expose both a portion of the non-bonding portion 134 and the first surface 112.

As further illustrated in FIG. 2, the bonding portion 132 of the metallization layer 130 can be physically, thermally, and/or electrically coupled to a conductive trace 136 that is insulated by the solder mask 120. In the illustrated embodiment, the trace 136 extends away from the bonding portion 132 between two of the second openings 124. In other embodiments, the trace 136 extends away from the bonding portion 132 and is exposed by at least one of the second openings 124. For example, the non-bonding portion 134 can include a portion of the trace 136 (and/or a portion of another trace extending away from another bonding portion).

As discussed above, the first opening 122 can have a larger footprint than any of the second openings 124. Further, the first opening 122 can have a different shape from the second openings 124. For example, as illustrated in FIG. 2, the first opening 122 can have a generally circular opening exposing the bonding portion 132 while each of the second openings 124 can have a generally rectangular shape. In various other embodiments, the second openings 124 can have any other suitable shape, such as generally circular shapes, semi-circles, arcuate shapes, any suitable polygon (e.g., hexagon, octagon, etc.), and the like.

As further illustrated in FIG. 2, the solder mask 120 can include a transition portion 222 surrounding the first opening 122. As illustrated, a portion (or all) of the transition portion 222 can overlap with and/or be formed over the bonding portion 132 of the metallization layer 130. The transition portion 222 spaces the vertical edge (or sidewall) of the first opening 122 from vertically apart with the vertical edge (or sidewall) of the bonding portion 132. As a result, the footprint of the first opening 122, and any solder structure formed thereon, can be reduced while providing access to bonding portion 132. As a result, additional connections to a corresponding bonding portion can be formed through the solder mask within a given footprint. As a result, the substrate 100 can shrink in longitudinal size and/or increase in functionality.

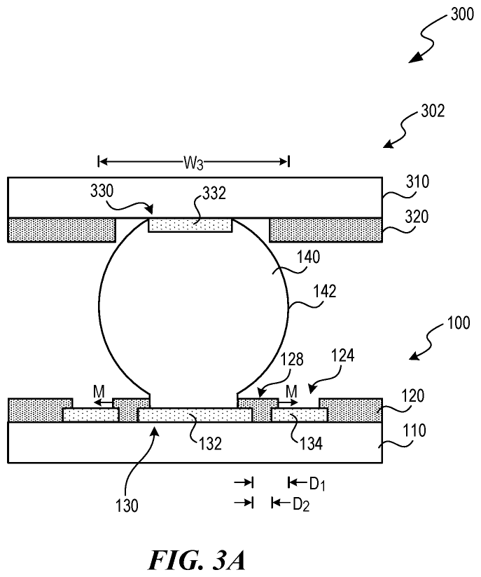

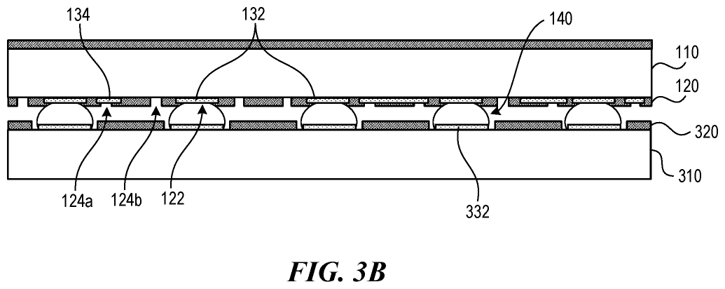

FIG. 3A is a partially schematic cross-sectional view of a semiconductor device 300 in accordance with some embodiments of the present technology. In the illustrated embodiment, the semiconductor device 300 includes a substrate 100 of the type discussed above with reference to FIGS. 1A-2. For example, the substrate 100 includes a core layer 110, a metallization layer 130 carried by a first surface 112 of the core layer 110, and a solder mask 120 carried by the first surface 112 and at exposing one or more portions of the metallization layer 130. For example, the solder mask 120 includes a first opening 122 exposing a bonding portion 132 and one or more second openings 124 (two shown). In the illustrated embodiment, each of the second openings 124 exposes a non-bonding portion 134 of the metallization layer. In various other embodiments, as discussed above, one or more of the second openings 124 can expose the first surface 112 of the core layer 110. In the illustrated embodiment, the substrate 100 can also include a solder structure 140 (e.g., a solder ball, conductive pillar, and/or any other suitable conductive feature) electrically coupled to the bonding portion 132 of the metallization layer 130.

As further illustrated in FIG. 3A, the semiconductor device 300 can also include a second component 302. The second component 302 can include a core layer 310, a metallization layer 330 carried by the core layer 310, and a solder mask 320 formed over the metallization layer 330 on the core layer 310 and exposing one or more bonding portions 332 (one shown, sometimes also referred to herein as “bond pads”) of the metallization layer 330. The second component 302 can be physically, thermally, and/or electrically coupled to the metallization layer 130 of the substrate 100 through the solder structure 140.

In various embodiments, the substrate 100 and the second component 302 can be any suitable features in a semiconductor package. For example, the substrate 100 can be a printed circuit board (PCB) and/or an interposer while the second component 302 can include one or more semiconductor dies and/or various active components. In another example, the substrate 100 can be a semiconductor die while the second component 302 includes one or more active features and/or another die stacked on top of the semiconductor die.

In any of these examples, as further illustrated in FIG. 3A, the inclusion of the second openings 124 can help relieve stress in the solder mask 120. In particular, the first opening 122 is immediately (or proximally) surrounded by a bonding region 128 of the solder mask. The bonding regions 128 of the solder mask 120 are in physical and thermal contact with the bonding portion 132 of the metallization layer 130 and the solder structure 140. However, each of the solder mask 120, the metallization layer 130, and the solder structure 140 can have a different coefficient of thermal expansion (CTE), which can result in various stress forces on the solder mask 120 when the substrate 100 is heated (e.g., when the solder structure 140 is formed and/or bonded to the second component 302, during operation of the semiconductor device 300, and the like).

As illustrated in FIG. 3A, the second openings 124 help release these stress forces by providing a space for the bonding region 128 of the solder mask 120 to move into (e.g., expanding and contracting along movement lines M). As a result, the second openings 124 can reduce the number of (or eliminate) stress-induced cracks that form in the solder mask 120 adjacent to the first openings 122 and/or reduce crack propagation. The reduction in cracks can improve the throughput of a manufacturing process (e.g., by reducing the number of substrates that are flawed due to the cracks) and improve the lifetime of the substrate 100.

By releasing the stress forces in the solder mask 120, the second openings 124 can also help reduce crack formation and/or propagation in other structures in the substrate 100. For example, by releasing the stress forces in the solder mask 120, the second openings 124 can also reduce stress forces on the metallization layer 130 and/or the core layer 110 when the substrate 100 is heated (e.g., by reducing stresses commuted through the solder mask 120). Further, by reducing crack formation and/or propagation in the solder mask 120, the second openings 124 can reduce the number of cracks that propagate out of the solder mask 120 and into the metallization layer 130 and/or the core layer 110. The reduction in cracks can also improve the throughput of a manufacturing process and improve the lifetime of the substrate 100.

Purely by way of example, the inventors conducted simulations, in accordance with IPC-9701A standards, on substrates that included the second openings and substrates that did not include the second openings. During the simulations, the exposed pads were daisy-chained together to detect the first failure in the substrate (e.g., since each of the first openings may expose critical-to-function pads), and electrical signals were cycled through the pads. The results showed that the substrates that included the second openings had an increased fatigue life (e.g., the number of cycles until the first failure) of between 4 and 8 percent. This increase in fatigue life can allow the substrates with the second openings to comply with stringent standards imposed on semiconductor components various industries (e.g., to comply with requirements in the automotive industry).

As further illustrated in FIG. 3A, the solder structure 140 has a third width W₃ that defines a longitudinal footprint having a peripheral edge 142. The peripheral edge 142 is the distalmost point of the solder structure 140 with respect to the first opening 122 and is longitudinally spaced apart from the first opening by a first distance D₁. The first distance D₁ imposes a limit on how closely packed a plurality of the first openings 122 can be without their corresponding solder structures 140 forming one or more shorts with one another. In particular, each of the first openings 122 must be spaced apart from each other by at least twice the first distance D₁ to provide enough space for the solder structures 140 to be formed without a short. In various embodiments, for example, the first distance D₁ can be between about 0.1 mm and about 0.4 mm.

This spacing also provides room for the second openings 124 to be formed. In the embodiment illustrated in FIG. 3A, for example, each of the second openings 124 is located at least partially within the longitudinal footprint of the solder structure 140. Said another way, at least a portion of each of the second openings 124 is vertically aligned with the solder structure 140. Said yet another way, and as further illustrated in FIG. 3A, each of the second openings 124 is spaced apart from the first opening 122 by a second distance D₂ that is smaller than the first distance D₁. For example, each of the second openings 124 can be spaced apart from the first opening 122 by a second distance D₂ that is smaller than twice the first distance D₁ (e.g., at a suitable intermediate position between two of the first openings 122 spaced farther apart than the minimum distance of twice the first distance D₁). In a specific, non-limiting example, the second distance D₂ can be between about 20 μm and about 100 μm. In a specific, non-limiting example, the second distance D₂ is about 50 μm. However, in various other embodiments, the second openings 124 can be spaced farther away from the first opening 122 than the peripheral edge 142 (e.g., when two of the first openings 122 share a single second opening 124, the second opening can be closer to one of the first openings and/or positioned half-way between the two).

FIG. 3B is a partially schematic, zoomed-out cross-sectional view of the semiconductor device 300 of FIG. 3A in accordance with some embodiments of the present technology. In the illustrated embodiment, the semiconductor device 300 includes a plurality of the solder structures 140 (one labeled, five shown). Each of the solder structures 140 is bonded between a corresponding bonding portion 132 of the metallization layer 130 on the substrate 100 and a bonding portion 332 of the metallization layer 330 on the second component 302, thereby physically, thermally, and/or electrically coupling the substrate 100 to the second component 302.

Each of the solder structures 140 are bonded to the corresponding bonding portion 132 of the metallization layer 130 on the substrate 100 through an individual one of the first openings 122 in the solder mask 120. Further, in the illustrated cross-section, the solder mask 120 includes two second openings 124 for each of the first openings 122 (e.g., an individual second opening 124 on each side of an individual one of the first openings 122). In other embodiments, as discussed above with reference to FIG. 1B, the solder mask 120 can include any other suitable ratio of second openings to first openings (e.g., 1:1, 3:1, 4:1, and/or any other suitable number). In some embodiments, the solder mask 120 includes a first ratio of the second openings to the first openings in a first direction (e.g., along the x-axis) and a second ratio of the second openings to the first openings in a second direction (e.g., along the y-axis) that is different from the first ratio.

As further illustrated in FIG. 3B, the solder mask 120 can include a combination of the metal second openings 124a (one labeled, five shown) and the substrate second openings 124b (one labeled, five shown). In various other embodiments, as discussed above, each of the second openings 124 can be positioned to expose only the core layer 110; each of the second openings 124 can be positioned to expose only a non-bonding portion 134 of the metallization layer 130; or one or more of the second openings 124 can be positioned to expose both a non-bonding portion 134 and the core layer 110. Each of the openings 124 can be positioned to expose only the core layer 110, for example, to reduce the exposure of the metallization layer 130.

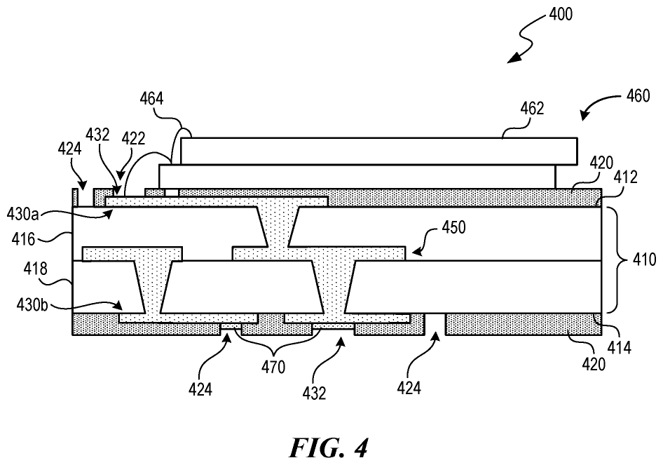

FIG. 4 is a partially schematic cross-sectional view of a semiconductor device 400 configured in accordance with some embodiments of the present technology. In the illustrated embodiment, the semiconductor device 400 (“device 400”) includes a substrate 402 and a die stack 460 carried by the substrate 402. The substrate 402 includes a core layer 410 that has a first side 412, a second side 414 opposite the first side 412, and first and second sub-portions 416, 418. The substrate also includes a first metallization layer 430a and a first solder mask 420a carried by the first side 412 of the core layer 410, as well as a second metallization layer 430b and a second solder mask 420b carried by the second side 414 of the core layer 410. The first metallization layer 430a is electrically coupled to the second metallization layer 430b by one or more vias 450 (sometimes also referred to herein as “interconnects”) extending through the core layer 410. The die stack 460 includes one or more dies 462 (two shown), each of which is electrically coupled to the first metallization layer 430a through a series of wirebonds 464.

Similar to the solder masks discussed above with reference to FIGS. 1A-3B, each of the first and second solder masks 420a, 420b can include one or more first openings 422 (one shown for each) and one or more second openings 424 (one shown for each). The first openings 422 each expose a bonding portion 432 (e.g., bond pads) of the first and second metallization layers 530a, 530b. The first and second metallization layers 530a, 530b, in conjunction with the vias 450, provide one or more (one shown) electrical connection routes between the first and second sides 412, 414 of the core layer 410. Accordingly, the first openings 422, by exposing the bonding portions 432, provide access to the electrical connection route(s) through the core layer 410.

Similar to the discussion above, the second openings 424 are positioned to alleviate stress in the first and second solder masks 420a, 420b around the first openings 422. In the illustrated embodiment, for example, a CTE mismatch between the wirebonds 464 and the bonding portion 432 exposed by the first opening 422 in the first solder mask 420a can result in stress on the first solder mask 420a. Similar to the discussion above with reference to FIG. 3A, the second openings 424 in the first solder mask 420a can help release the stress by providing space for the first solder mask 420a to expand into. In another example, a solder ball (or other conductive structure) coupled to the bonding portion 432 exposed by the first opening 422 in the second solder mask 420b can result in stress on the second solder mask 420b. In this example, the second openings 424 in the second solder mask 420b can help release the stress by providing space for the second solder mask 420b to expand into. In both examples, the second openings 424 can help mitigate crack formation and/or propagation, thereby improving the life expectancy of the device 400 and/or a manufacturing process resulting in the device 400.

As further illustrated in FIG. 4, the substrate 402 can include a surface finishing material 470 covering the portions of the second metallization layer 430b exposed by the first and second openings 422, 424 in the second solder mask 420b. The surface finishing material 470 can provide a protective layer that prevents the exposed portions of the second metallization layer 430b from physical and/or chemical damage before another conductive structure (e.g., a solder ball) is coupled to the second metallization layer 430b. In various embodiments, the surface finishing material 470 can result from an organic solderability preservative, hot air solder leveling, immersion tin, immersion silver, electroless nickel immersion, and/or various other suitable processes. In some embodiments, the substrate 402 includes the surface finishing material 470 covering every exposed portion of a metallization layer (e.g., including the exposed portions of the first metallization layer 430a).

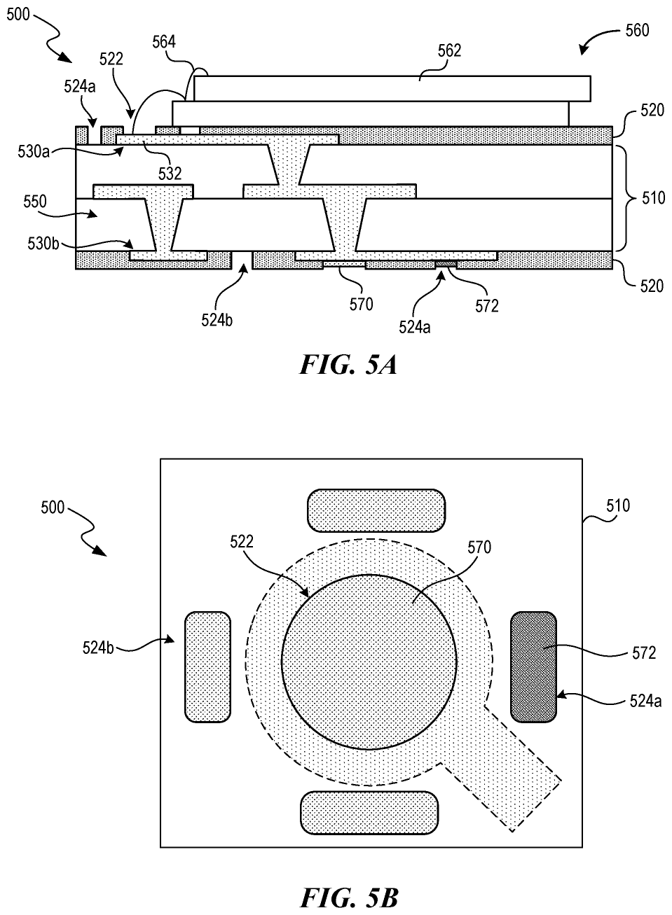

FIGS. 5A and 5B are partially schematic cross-sectional and bottom plan views, respectively, of a semiconductor device 500 configured in accordance with some embodiments of the present technology. The semiconductor device 500 (“device 500”) is generally similar to the device 400 discussed above with reference to FIG. 4. For example, as best illustrated in FIG. 5A, the device includes a substrate 502 and a die stack 560, carried by the substrate 502. The substrate 520 includes a core layer 510 that has a first side 512, a second side 514 opposite the first side 512, and first and second sub portions 516, 518. The substrate also includes a first metallization layer 530a and a first solder mask 520a carried by the first side 512 of the core layer 510, as well as a second metallization layer 530b and a second solder mask 520b carried by the second side 514 of the core layer 510. One or more vias 550 (sometimes also referred to herein as “interconnects”) electrically coupled the first metallization layer 430a and the second metallization layer 430b through the core layer 410. The die stack 460 includes one or more dies 562 (two shown), each of which is electrically coupled to the first metallization layer 530a through a series of wirebonds 564. Further, the substrate 502 includes a surface finishing material 570 protecting the bonding portion 532 of the second metallization layer 530b exposed by the first opening 522 in the second solder mask 520b.

Still further, as illustrated in FIGS. 5A and 5B, the second solder mask 520b includes one or more metal second openings 524a (one shown) and one or more substrate second openings 524b (one shown in FIG. 5A, three shown in FIG. 5B). Similar to the discussion above with reference to FIGS. 1C-3A, the metal second opening 524a exposes a non-bonding portion 534 of the second metallization layer 530. However, in the illustrated embodiment, the substrate 502 includes coupled to the non-bonding portion 534 exposed through the second solder mask 520b. The conductive layer 572 can both protect the non-bonding portion 534 from physical and/or chemical damage and provide a testing bond pad adjacent to the bonding portion 532 that can allow the performance of the substrate 502 to be measured at various points of manufacturing. For example, the conductive layer 572 can allow the electrical signal routes through the core layer 510 to be tested before a conductive structure (e.g., a solder ball) is formed on the bonding portion 532 (thereby breaking through the surface finishing material 570).

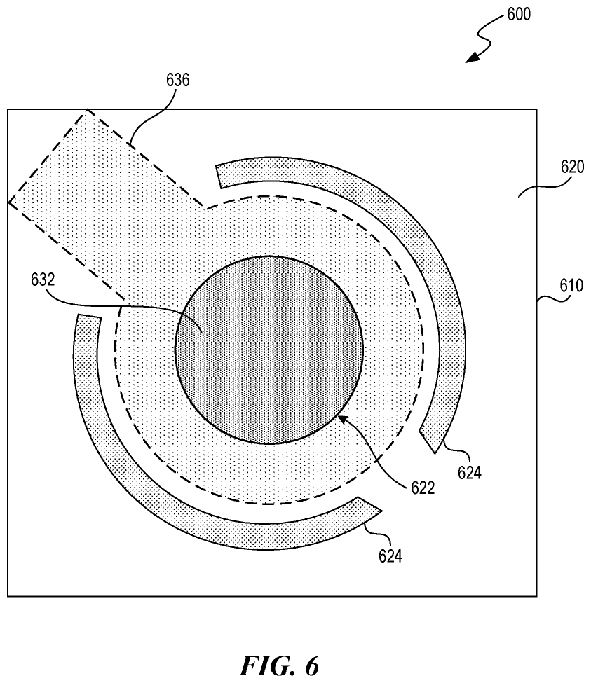

FIG. 6 is a partially schematic top view of a substrate 600 for use with a semiconductor device configured in accordance with some embodiments of the present technology. Similar to the substrate 100 discussed above with reference to FIG. 2, the substrate 600 includes a core layer 610, a metallization layer 630 deposited over the core layer 610, and a solder mask 620 deposited over the metallization layer 630. Further, the solder mask 620 includes a first opening 622 exposing a bonding portion 632 (e.g., a bond pad) of the metallization layer 630 and one or more second openings 624 (two shown) positioned to release stress from the solder mask 620 around the first opening 622. In the illustrated embodiment, however, the second openings 624 have an arcuate shape surrounding a portion of the perimeter of the first opening 622. The arcuate shape can allow the second openings 624 to provide more complete coverage around the perimeter of the first opening 622 (e.g., as compared to the second openings 124 discussed above with reference to FIG. 2). This coverage, in turn, can help further reduce crack formation and/or propagation by providing space for the solder mask 620 to expand.

As discussed above, the second openings 624 can have various other suitable shapes and/or sizes. Purely by way of example, the second openings 624 can have circular shapes formed intermittently around the perimeter of the first opening 622. In another example, the second openings 624 can have a single arcuate shape surrounding a portion (or all) of the perimeter of the first opening 622 (e.g., omitting the illustrated interruption opposite the trace 636).

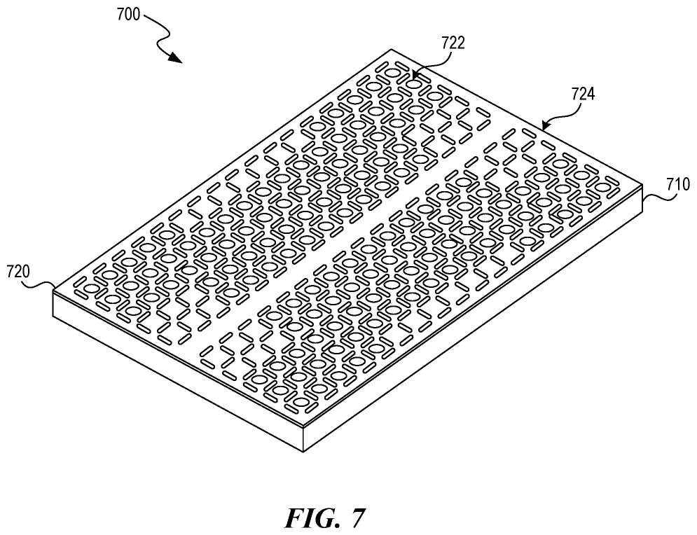

FIG. 7 is a partially schematic isometric view of a substrate 700 configured in accordance with further embodiments of the present technology. As illustrated in FIG. 7, the substrate 700 is generally similar to the substrate 100 discussed above with reference to FIG. 1A. For example, the substrate 700 includes a core layer 710 and a solder mask 720 deposited over a surface 712 (e.g., an upper surface) of the core layer 710. Further, the solder mask 720 can insulate and selectively expose a metallization layer (e.g., the metallization layer 130 discussed above with reference to FIG. 1B) at the surface 712 of the core layer 710. For example, the solder mask 720 includes a plurality of first openings 722, each of which can expose a bonding portion (e.g., a bond pad or other conductive structure) of the metallization layer. Still further, the solder mask 720 also includes a plurality of second openings 724.

However, in the illustrated embodiment, a first subset of the second openings 724 are positioned to release stress from the solder mask 720 around a corresponding one of the first openings 722 while a second subset of the second openings 724 are not positioned adjacent to any current opening and/or structure. The illustrated embodiment can result, for example, from an indiscriminate pattern formation that is a more economical process (e.g., forming the same grid regardless of the number of first openings 722 included in the solder mask 720). Additionally, or alternatively, the illustrated embodiment can allow additional openings to be formed in the solder mask 720 in later manufacturing with a reduced risk of crack formation and/or propagation.

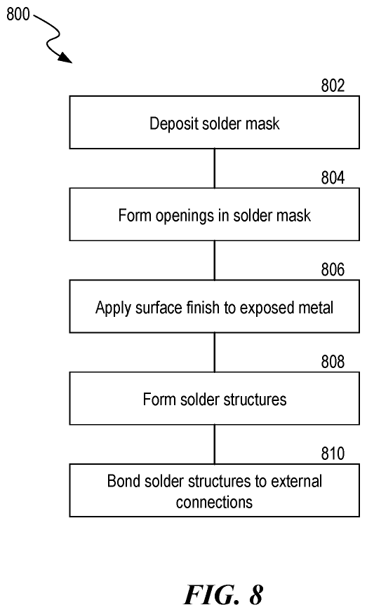

FIG. 8 is a flow diagram of a process 800 for manufacturing a substrate of the type discussed above with respect to FIGS. 1A-7 in accordance with some embodiments of the present technology. In the illustrated embodiment, the process 800 begins at block 802 with depositing a solder mask on a surface of a core layer. The solder mask can provide physical and/or chemical protection, electrical insulation, and/or thermal insulation to a metallization layer on the surface of the substrate. The solder mask can be deposited by any suitable process, such as a screen-printing process, a blanket deposition, a dry film process, and the like. In some embodiments, after deposition, the process 800 includes drying and/or partially curing the solder mask (e.g., in a kiln).

At block 804, the process 800 includes forming openings in the solder mask. The process 800 can form both the firm and second openings at the same time or can form the first and second openings sequentially. In various embodiments, the forming of the openings can include a photoimaging process (e.g., using exposure under ultraviolet light), an etching process, and/or any other suitable, selective process.

At block 806, the process 800 includes applying a surface finish to any metal exposed by the openings formed at block 804. As discussed above, the surface finishing material can provide physical and/or chemical protection to the exposed metal until a conductive structure (e.g., a solder ball) is formed thereon. In various embodiments, the surface finishing process at block 806 can include hot air solder leveling, organic solderability preservative, immersion tin, matte tin, immersion silver, immersion gold, electroless nickel immersion, and the like.

At block 808, the process 800 includes forming conductive structures on at least some of the metal exposed by the openings in the solder mask. For example, the process 800 can include forming solder balls (or other suitable structures) on one or more bonding portions (e.g., bond pads, vias, and the like) of the metallization layer that are exposed by the first openings formed in the solder mask. In another example, the process 800 can include forming testing bond pads on one or more non-bonding portions of the metallization layer that are exposed by second openings formed in the solder mask.

In some embodiments, the process 800 omits block 806 and does not form a surface finishing material on the metal exposed through the openings. For example, the surface finishing material can be unnecessary when there is minimal transport and/or exposure between forming the openings at block 804 and forming the conductive structures at block 808.

At block 810, the process 800 includes bonding the conductive structures to external connections. For example, the solder structures formed at block 810 can be bonded to additional components of a semiconductor package (e.g., dies) and/or devices external to a package (e.g., a carrier, a motherboard, and the like). In another example, the testing bond pads can be coupled to a wirebond (or other suitable connection) to execute a testing process (e.g., evaluating the electrical signal routes through the substrate).

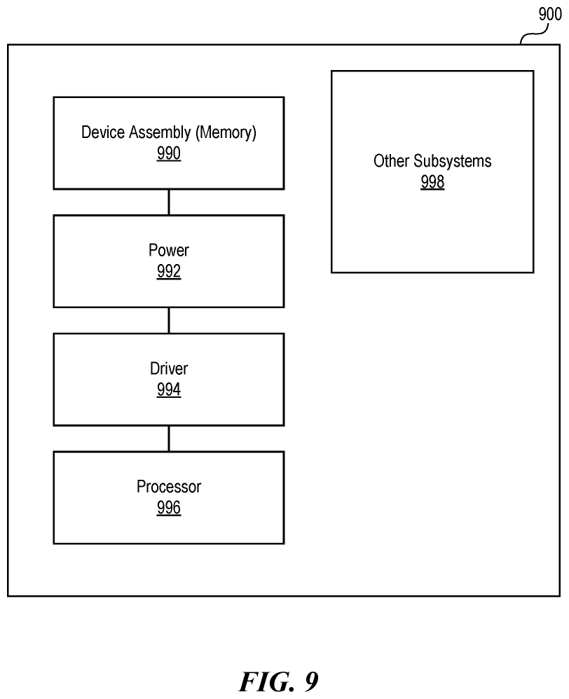

FIG. 9 is a schematic view of a system that includes a semiconductor die assembly configured in accordance with embodiments of the present technology. Any one of the semiconductor devices having the nano stress-releasing features discussed above with respect to FIGS. 1A-7 and/or resulting from the processes described above with reference to FIG. 8 can be incorporated into any of a myriad of larger and/or more complex systems, a representative example of which is system 900 shown schematically in FIG. 9. The system 900 can include a memory 990 (e.g., SRAM, DRAM, flash, and/or other memory devices), a power supply 992, a drive 994, a processor 996, and/or other subsystems or components 998. Semiconductor devices having substrates of the type discussed above with respect to FIGS. 1A-7 and/or resulting from the process discussed above with respect to FIG. 8 can be included in any of the elements shown in FIG. 9. For example, the memory 990 can include a package substrate having a solder mask with the first and second openings discussed above to improve the lifetime of the memory 990 and/or the system 900 (e.g., by mitigating crack propagation and/or formation in the PCB).

The resulting system 900 can be configured to perform any of a wide variety of suitable computing, processing, storage, sensing, imaging, and/or other functions. Accordingly, representative examples of the system 900 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 900 include lights, cameras, vehicles, etc. In a specific, non-limiting example, the resulting system 900 can be used in an automotive package, where requirements on package fatigue lives is especially high. With regard to these and other examples, the system 900 can be housed in a single unit or distributed over multiple interconnected units, e.g., through a communication network. The components of the system 900 can accordingly include local and/or remote memory storage devices and any of a wide variety of suitable computer-readable media.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10 percent of a given value or limit. Purely by way of example, an approximate ratio means within ten percent of the given ratio.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A substrate for a semiconductor device assembly, the substrate comprising:
a core layer having an outer surface;
a metallization layer formed on the outer surface, the metallization layer including at least one bond pad and a trace electrically coupled to the at least one bond pad; and
a solder mask formed over the metallization layer and the outer surface, wherein the solder mask includes:
a first opening exposing the at least one bond pad and immediately surrounded by a bonding region of the solder mask; and
one or more second openings adjacent the first opening, wherein each of the one or more second openings is configured to provide space for the bonding region of the solder mask to expand into during a thermal expansion of a solder ball formed on the at least one bond pad.

2. The substrate of claim 1, wherein the first opening has a first cross-sectional area, and wherein each of the one or more second openings has a second cross-sectional area smaller than the first cross-sectional area.

3. The substrate of claim 1, wherein the first opening has a first longitudinal footprint, and wherein each of the one or more second openings has a second longitudinal footprint different from the first longitudinal footprint.

4. The substrate of claim 1, wherein at least a portion of one of the one or more second openings is vertically aligned with the solder ball formed on the at least one bond pad.

5. The substrate of claim 1, wherein at least one of the one or second openings exposes the outer surface of the core layer.

6. The substrate of claim 1, wherein the first opening has a first depth, and wherein at least one of the one or second openings has a second depth greater than the first depth.

7. The substrate of claim 1, wherein at least one of the one or second openings exposes a non-bond pad portion of the metallization layer.

8. The substrate of claim 7, further comprising a surface finishing material covering the at least one bond pad exposed by the first opening in the solder mask and the non-bond pad portion exposed by the second opening in the solder mask.

9. The substrate of claim 8, wherein the surface finishing material is an organic solderability preservative.

10. The substrate of claim 1, wherein the solder mask further includes a third opening adjacent one of the one or more second openings, wherein the third opening exposes a second bond pad of the metallization layer.

11. A substrate for a semiconductor device, comprising:
a layer having an upper surface;
a metallization layer formed on the upper surface, the metallization layer including a plurality of bond pads;
a solder mask formed over the metallization layer and the upper surface, wherein the solder mask includes:
a plurality of first openings, wherein each of the plurality of first openings exposes an individual one of the plurality of bond pads of the metallization layer; and
a plurality of second openings adjacent each of the plurality of first openings, wherein each of the plurality of second openings provides longitudinal space for portions of the solder mask proximate the plurality of first openings to expand into; and
a plurality of solder structures each corresponding to an individual one of the plurality of first openings, wherein each of the plurality of solder structures is electrically coupled to the individual bond pad exposed by the individual first opening.

12. The substrate of claim 11, wherein the substrate includes a central region, and wherein each of the plurality of bond pads in the metallization layer is carried by the central region.

13. The substrate of claim 11, wherein the plurality of second openings in the solder mask form a grid, and wherein each of the plurality of first openings is positioned surrounded by two or more corresponding second openings in the grid.

14. The substrate of claim 11, wherein each of the plurality of first openings has a first footprint, and wherein each of the plurality of second openings has a second footprint smaller than the first footprint.

15. The substrate of claim 11, wherein one or more of the plurality of second openings exposes the upper surface of the substrate.

16. The substrate of claim 11, wherein the structure has a longitudinal footprint defining a peripheral edge, wherein a point on the peripheral edge is spaced longitudinally apart from the first opening by a first distance, and wherein the each of the second openings is at least partially within a second distance from the first opening that is twice the first distance.

17. The substrate of claim 11, wherein the substrate further includes a plurality of vias extending through the substrate, and wherein the metallization layer is electrically coupled to each of the plurality of vias.

18. A method for reducing solder mask cracking while forming a semiconductor device, the method comprising:
depositing s solder mask over a metallization layer and a surface of a first component, wherein the metallization layer includes one or more bond pads and a conductive trace extending away from each of the one or more bond pads;
forming a plurality of openings in the solder mask, the plurality of openings including:
one or more first openings each exposing a corresponding bond pad of the metallization layer, wherein each of the one or more first openings has a first longitudinal footprint; and
a plurality of second openings adjacent each of the one or more first openings, wherein each of the plurality of second openings has a second longitudinal footprint different from the first longitudinal footprint;
forming a solder structure on each of the corresponding bond pads exposed by the one or more first openings; and
bonding the solder structure to a bonding feature on a second component.

19. The method of claim 18, wherein at least one of the plurality of second openings exposes a non-bond pad portion of the metallization layer, and wherein the method further comprises applying a surface finish to each of the corresponding bond pads exposed by the one or more first openings and each of the non-bond pad portions exposed by the plurality of second openings.

20. The method of claim 18, wherein at least one of the plurality of second openings exposes the surface of the first component, and wherein forming the plurality of openings in the solder mask includes:
forming the one or more first openings to a first depth beneath an outer surface of the solder mask; and
forming the second openings that expose the surface of the first component at a second depth beneath the outer surface of the solder mask, wherein the second depth is larger than the first depth.
